(19) United States
(12) Patent Application Publication
(10) Pub. No.: US 2015/0022194 A1
(43) Pub. Date: Jan. 22, 2015

(54) MAGNETOMETER FOR ALIGNING A PORTABLE DEVICE ON A PLANAR CHARGING SURFACE OF AN INDUCTIVE CHARGING UNIT

(71) Applicant: Blackberry Limited, Waterloo (CA)

(72) Inventors: Nazih ALMALKI, Waterloo (CA); George Albert DOSKOW, Boynton Beach, FL (US); Michelle Marie DUPUIS, Boca Raton, FL (US); Glenn L. MONROE, Boca Raton, FL (US); Joseph PATINO, Miramar, FL (US)

(21) Appl. No.: 13/945,426

(22) Filed: Jul. 18, 2013

(51) Int. Cl. G01R 33/02; H02J 7/00; H02J 7/02

(52) U.S. Cl. CPC G01R 33/02; H02J 7/025; H02J 7/0047
USPC 324/244

(57) ABSTRACT

A portable electronic uses a magnetometer to determine an alignment with an inductive charging unit magnetic charging field. The alignment increases a portion of the magnetic charging field generated by the inductive charging unit and received by the portable device to better power the device and reduce battery recharge times. The portable device displays motion icons to facilitate a manual alignment. The magnetometer may also be used for magnetic earthly field applications such as a compass, navigation and augmented reality.

The present disclosure generally relates to the wireless provision of power to a portable device for purposes including battery charging, and particularly to alignment of a portable device upon an inductive charging surface for the wireless provision of power.

### BACKGROUND

Inductive charging units having planar charging surfaces that enable a wireless provision of power to portable devices. Portable devices include cell phones, smart phones, super phones, gaming devices, personal information managers, tablets, personal computers, music players and wireless headsets. The planar charging surface is a substantially flat surface for supporting a wide variety of portable devices and interfaces to a planar receiving surface of the portable device by contacting the planar receiving surface, which is generally smaller than the planar charging surface. The planar charging surface transmits a localized magnetic charging field (or more than one localized magnetic charging field) for reception by a receiving coil of the portable device. The planar receiving surface of the portable device is a substantially flat surface and accommodates interfacing with a wide variety of inductive charging units. The magnetic charging field is converted to electrical power for use by the portable device. Uses include recharging a battery of the device and operating the device.

The planar charging surface has the advantage of allowing any of a number of present and future portable devices to be set upon or proximate to the planar charging surface for the transfer of power and further allows a portable device to receive power from any number of present and future inductive charging units. No wires, plugs, cables, sockets, adapters or other type of physical connection means are required. Conveniently, the geometry of the portable device is not constrained to a particular charging cradle, dock or mounting apparatus. To add to convenience, a specific orientation of the portable device is not required. The portable device is simply set proximate to the planar charging surface with any orientation and without any further physical connection. Placing the portable device proximate to the planar charging surface includes the portable device being positioned relative to the inductive charging unit in any of a number or orientations, the orientations including the portable device being set on top of, adjacent to, parallel with, in contact with, in the vicinity of, near to or otherwise close to inductive charging unit such that at least a portion of the magnetic charging field is received by the portable device.

### BRIEF DESCRIPTION OF THE DRAWINGS

The accompanying figures where like reference numerals refer to identical or functionally similar elements throughout the separate views, and which together with the detailed description below are incorporated in and form part of the specification, serve to further illustrate various embodiments and to explain various principles and advantages all in accordance with the present disclosure, in which:

FIG. 1 illustrates a representative block diagram of a portable device having a magnetometer for aligning the portable device on a planar charging surface of an inductive charging unit;

FIG. 2 illustrates a representative example of flow diagram for a portable device using a magnetometer for aligning the portable device on a planar charging surface of an inductive charging unit;

FIG. 3 illustrates a flow diagram of a first example of a charging alignment process using a magnetic direction signal from a magnetometer;

FIG. 4A illustrates a first example of aligning a portable device on a planar surface of an inductive charging unit with a magnetometer using the charging alignment process of FIG. 3;

FIG. 4B illustrates a second example of aligning a portable device on a planar surface of an inductive charging unit with a magnetometer using the charging alignment process of FIG. 3;

FIG. 5 illustrates a flow diagram of a second example of a charging alignment process using a magnetic direction signal from a magnetometer;

FIG. 6A, FIG. 6B and FIG. 6C illustrate an example of aligning a portable device on a planar surface of an inductive charging unit with a magnetometer using the charging alignment process of FIG. 5; and

FIG. 7 illustrates a representative block diagram of an electronic device and associated components that are able to include the above described systems and perform the above described methods.

### DETAILED DESCRIPTION

Discussed herein are methods an apparatus by which a portable device can be positioned relative to a magnetic charging field to transfer power efficiently from an inductive charging unit to the portable device. Generally speaking, a magnetic field may extend over an arbitrary volume, but there are portions (or regions) of the field that are stronger than others. Alignment of the receiving coil of the portable device relative to the magnetic charging field, in which the receiving coil is oriented and moved closer to a stronger portion of the field, is a factor in determining an amount of power that can be transferred from the inductive charging unit to the portable device. More efficient transferring power can reduce battery recharge times and provide additional operating power to the portable device. The higher transfer of power can be accomplished by moving the portable device upon the planar charging surface to a location where a greater portion of the magnetic charging field is received by the receiving coil of the portable device.

An inductive charging unit has a transmitting coil for generating the magnetic charging field. Matching the dimensions and electrical characteristics of the transmitting coil to the dimensions and electrical characteristics of the receiving coil and locating the receiving coil in a standard location with corresponding alignment fiducials could facilitate a higher or more efficient transfer of power, but this would detract from the convenience of the device. Given the wide variety of wireless charging unit applications and manufacturers and the similar wide variety of portable device applications and manufacturers, maintaining a common transmitting and receiving coil and requiring their uniform location becomes an impractical solution to facilitating a higher transfer of power.

As will be described below, a magnetometer can be employed to sense the magnetic charging field. The magnetometer may be responsive to, and be able to sense, the shape of the field, for example, or the strength or weakness of the field, or where or in what direction the field is stronger or weaker. A magnetic direction signal from the magnetometer may be received by a controller, which can determine in which direction the portable device may be moved to improve the alignment. The controller may be informed or instructed (e.g., via a visual display) how the portable device may be moved to improve the alignment. The magnetometer need not be limited to such functions. Indeed, portable devices can include magnetometers to perform other functions, such as to measure the magnetic field of the Earth for applications such as an electronic compass, and determining a magnetic heading of the portable device for applications such as navigation and augmented reality. A magnetometer may therefore perform or participate in a variety of functions.

As required, detailed embodiments are disclosed herein; however, it is to be understood that the disclosed embodiments are merely examples and that the systems and methods described below can be embodied in various forms. Therefore, specific structural and functional details disclosed herein are not to be interpreted as limiting, but merely as a basis for the claims and as a representative basis for teaching one skilled in the art to variously employ the disclosed subject matter in virtually any appropriately detailed structure and function. Further, the terms and phrases used herein are not intended to be limiting, but rather, to provide an understandable description.

The terms “a” or “an”, as used herein, are defined as one or more than one. The term plurality, as used herein, is defined as two or more than two. The term another, as used herein, is defined as at least a second or more. The terms “including” and “having,” as used herein, are defined as comprising (i.e., open language). The term “coupled,” as used herein, is defined as “connected,” although not necessarily directly and includes communicatively coupled components which may include electrically coupled components, mechanically coupled components or both. In the context of the following description, some components may be coupled communicatively, such that one may communicate with the other. In some cases, communicative coupling can be achieved by electrical coupling, in which one component may pass electrical signals to the other. In different contexts, some components may be coupled to one another mechanically or physically. The term “configured to” describes hardware, software or a combination of hardware and software that is adapted to, set up, arranged, built, composed, constructed, designed or that has any combination of these characteristics to carry out a given function. The term “adapted to” describes hardware, software or a combination of hardware and software that is capable of, able to accommodate, to make, or that is suitable to carry out a given function. In the following discussion, “handheld” is used to describe items, such as “handheld devices,” that are sized, shaped, designed or otherwise configured to be carried and operated while being held in a human hand.

Described below, in one example a method in a portable device comprises receiving a magnetic direction signal from a magnetometer, the magnetic direction signal indicative of a portion of a magnetic charging field received the portable device and generating, based on the magnetic direction signal, a motion signal indicative of a movement of the portable device, the movement determined to increase the portion of the magnetic charging field received by the portable device. The magnetometer also receives a magnetic earthly field and the method further comprises processing the magnetic direction signal to determine a direction of the magnetic earthly field based on a determined absence of the magnetic charging field. The processing includes processing the magnetic direction signal by at least one of a compass process, a navigation process and an augmented reality process. The method further includes rendering a movement icon on a display of the portable device based on the motion signal. The movement icon is indicative of at least one of a translational motion of the portable device and a rotational motion of the portable device. The motion signal is generated based on the magnetic direction signal and a look-up table. The portable device includes a receiving coil for receiving the portion of the magnetic charging field and producing an amount of received power, and the motion signal is indicative of a direction of movement that increases the portion of the magnetic charging field received by the receiving coil. The portable device includes a power manager coupled to the receiving coil, the power manager determining the amount of received power and the generating generates the motion signal further based on the amount of received power. The motion signal is indicative of a stopping of the movement based on the amount of received power being greater than a threshold. Based on the amount of received power being less than the threshold, the motion signal is generated based on the magnetic direction signal and a look-up table. The magnetometer and the receiving coil have locations within the portable device that define a direction of alignment, and further wherein the motion signal is generated based on the magnetic direction signal and the direction of alignment. The motion signal indicates a rotational movement of the portable device to align a direction of the magnetic direction signal with a direction of the direction of alignment. The portable device further comprises a power manager coupled to the receiving coil for determining the amount of received power and the generating generates the motion signal further based on the amount of received power. The motion signal indicates a translational movement of the portable device determined to increase the amount of received power. The motion signal is indicative of a stopping of the movement based on the amount of received power either one of achieving a maximum, and being greater than a threshold.

In another example, a portable device comprises a receiving coil for receiving a portion of a magnetic charging field, a magnetometer for generating a magnetic direction signal indicative of the magnetic charging field, and a controller for generating a motion signal based on the magnetic direction signal, the motion signal indicative of a movement of the portable device determined to increase the portion of the magnetic charging field received by the receiving coil. The magnetometer also receives a magnetic earthly field and the controller processes the magnetic direction signal to determine a direction of the magnetic earthly field based on a determined absence of the magnetic charging field, and the portable device further comprises a magnetic earthly field processor for implementing at least one of a compass process, a navigation process and an augmented reality process based on the direction of the magnetic earthly field. A display renders a movement icon indicative of the motion signal, the movement icon being indicative of at least one of a translational motion of the portable device and a rotational motion of the portable device. The receiving coil receives the portion of the magnetic charging field and produces an amount of received power and the motion signal is determined to increase the portion of the magnetic charging field received by the receiving coil, and the portable device further comprises a power manager coupled to the receiving coil for determining the amount of received power and the motion signal is further generated based on the amount of received power, wherein the magnetometer and the receiving coil have locations within the portable device that define a direction of alignment, and further wherein the motion signal is generated based on the direction of alignment.

In another example, a method in a portable device comprising processing a magnetic direction signal indicative of a portion of a magnetic charging field transmitted at a planar charging surface of an inductive charging unit and received at a planar receiving surface of the portable device, the planar receiving surface being proximate to the planar charging surface, and generating a motion signal indicative of a manual movement of the portable device determined to increase the portion of the magnetic charging field received by the portable device based on the magnetic direction signal. The magnetic direction signal is generated by a magnetometer also receiving a magnetic earthly field and the method further comprises processing the magnetic direction signal to determine a direction of the magnetic earthly field based on a determined absence of the magnetic charging field. The processing includes processing the magnetic direction signal by at least one of a compass process, a navigation process and an augmented reality process. The method further comprises rendering a movement icon on a display of the portable device indicative of the motion signal. The movement icon is indicative of at least one of a translational motion of the portable device and a rotational motion of the portable device. The motion signal is generated based on the magnetic direction signal and a look-up table. The portable device includes a receiving coil for receiving the portion of the magnetic charging field and producing an amount of received power, and the motion signal is determined to increase the portion of the magnetic charging field received by the receiving coil. The portable device includes a power manager coupled to the receiving coil determining the amount of received power and the generating generates the motion signal further based on the amount of received power. The motion signal is indicative of a stopping of the manual movement based on the amount of received power being greater than a threshold. The amount of received power being less than the threshold, the motion signal is generated based on the magnetic direction signal and a look-up table. The portable device further includes a magnetometer for generating the magnetic direction signal, the magnetometer and the receiving coil having locations within the portable device that define a direction of alignment, and further wherein the motion signal is generated based on the magnetic direction signal and the direction of alignment. The motion signal indicates a rotational manual movement of the portable device to align a direction of the magnetic direction signal with a direction of the direction of alignment. The portable device includes a power manager coupled to the receiving coil for determining the amount of received power and the generating generates the motion signal further based on the amount of received power. The motion signal indicates a translational manual movement of the portable device determined to increase the amount of received power. The motion signal is indicative of a stopping of the manual movement based on the amount of received power either one of achieving a maximum, and being greater than a threshold.

In another example, a portable device comprises a magnetometer for generating a magnetic direction signal indicative of a portion of a magnetic charging field transmitted at a planar charging surface of an inductive charging unit and received at a planar receiving surface of the portable device, the planar receiving surface being proximate to the planar charging surface, and a controller for generating a motion signal indicative of a manual movement of the portable device determined to increase the portion of the magnetic charging field received by the portable device based on the magnetic direction signal. The magnetometer also receives a magnetic earthly field and the controller further processes the magnetic direction signal to determine a direction of the magnetic earthly field based on a determined absence of the magnetic charging field for use by at least one of a compass process, a navigation process and an augmented reality process. The portable device according further comprises a display for rendering a movement icon indicative of the motion signal, the movement icon being indicative of at least one of a translational motion of the device and a rotational motion of the portable device. The portable device according further comprises a receiving coil for receiving the portion of the magnetic charging field and producing an amount of received power, and the motion signal is determined to increase the portion of the magnetic charging field received by the receiving coil, and a power manager coupled to the receiving coil determining the amount of received power and the motion signal is further generated based on the amount of received power, wherein the magnetometer and the receiving coil having locations within the portable device that define a direction of alignment, and further wherein the motion signal is generated based on the magnetic direction signal and the direction of alignment.

In another example implementation, a non-transitory computer readable medium having a stored set of instructions that when executed cause an apparatus to process a magnetic direction signal indicative of a portion of a magnetic charging field transmitted at a planar charging surface of an inductive charging unit and received at a planar receiving surface of the portable device, the planar receiving surface being proximate to the planar charging surface, generate a motion signal indicative of a manual movement of the portable device determined to increase the portion of the magnetic charging field received by the portable device based on the magnetic direction signal, and process the magnetic direction signal to determine a direction of a magnetic earthly field based on a determined absence of the magnetic charging field.

The below described examples may provide several advantages; in one example, a portable device has a display for rendering icons for locating the portable device on an inductive charging unit in order to provide an increased reception of a magnetic charging field by the receiving coil of the portable device. The user may, at a glance, determine where the portable device may be positioned for efficient power transfer. This allows for reduced battery charging times while also providing for numerous types and configurations of portable devices to be located on numerous types and configurations of inductive charging units. The physical interface between the inductive charging unit and the portable device is a simple corresponding pair of planar interfaces set proximate to each other.

The proximate relationship between the planar charging surface and the planar receiving surface in one example includes the surfaces being placed in contact with, interfacing with, parallel to, adjacent to, next to, in the vicinity of, or in close proximity with or to each other in order to facilitate reception of the magnetic charging field by the receiving coil of the portable device. There is no precise numerical measurement for proximity for inductive charging, but in many cases, the portable device and the charging surface are 1 cm or less from one another. If the planar charging surface has a horizontal upward orientation, then the proximate relationship can correspond to the portable device simply being placed on top of the planar charging surface. Another potential advantage is the multiple use of a magnetometer which may be used for both magnetic earthly field applications, such as a compass, as well as portable device alignment relative to the inductive charging unit. This not only allows for the increased reception of the magnetic charging field, but also reduces costs associated with a portable device having both magnetic earthly field applications and the portable device alignment application because the magnetometer is shared and additional materials costs may be reduced or not required. Sharing of functions of components may be especially useful for portable devices in general, and handheld devices in particular, in which considerations of size and weight are important.

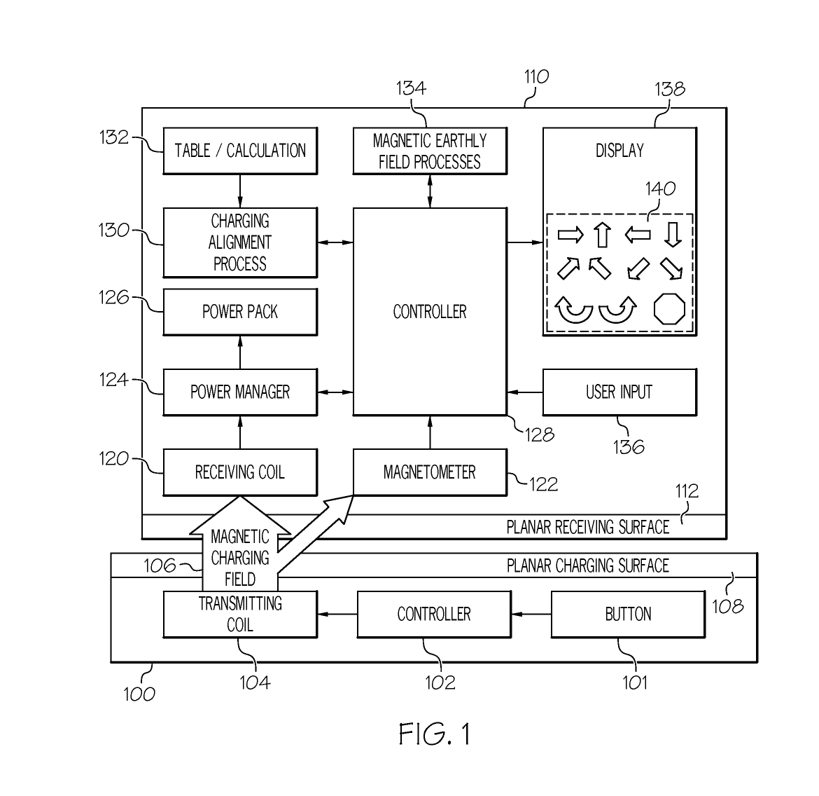

FIG. 1 illustrates a representative block diagram of a portable device having a magnetometer for aligning the portable device on a planar charging surface of an inductive charging unit. Inductive charging unit 100 has a button 101 for manually activating a controller 102 for controlling the operation of a transmitting coil 104 for generating a magnetic charging field 106 that is transmitted through a planar charging surface 108. An inductive charging unit includes any device providing wireless power or wireless energy transmission using a magnetic field. The construction and operation of the inductive charging unit is known to those familiar with the art and may include a wireless data link to the portable device either through modulation of the magnetic charging field or other wireless means known to those familiar with the art such as Bluetooth, WiFi, Zigbee or NFC.

The planar charging surface of an example may be orientated horizontally on a top surface of the charging unit and is adapted to receive a planar surface of a portable device for the transfer of power. The planar charging surface may include any surface with a low or high friction component and may be a soft or a hard surface that may be smooth or textured. The planar charging surface is larger and allows for translational and rotational movements of the portable device while maintaining the proximate relationship between the planar charging surface and the planar receiving surface. Translational manual movement of the portable device includes combinations of up, down, left and right motions. Rotational manual movement of the portable device includes clockwise and counterclockwise motions. The weight of the portable device generally secures its proximate relationship with the inductive charging unit. Other mechanical connections are not required. A user simply places a portable device on the inductive charging unit with the planar receiving surface contacting the planar charging surface. When portability is desired, the user simply picks up the portable device and takes it on its way, ideally with a fully charged battery.

Portable device 110 in one example has a planar receiving surface 112 for interfacing with the planar charging surface 108 of the inductive charging unit. Portable device 110 can be any of a multiplicity of portable devices for receiving power from the inductive charging unit including pagers, personal digital assistants, e-readers, cell phones, smart phones, super phones, tablets, convertible PCs, laptops, gaming systems, entertainment systems, music players, headsets, other such devices or combinations of these. The planar receiving surface may be orientated horizontally on a rear surface of the portable device and is able to be adapted to interface with the planar charging surface of an inductive charging unit for the transfer of power. The planar receiving surface may include any surface with a low or high friction component and may be a soft or a hard surface that may be smooth or textured. The planar receiving surface is generally smaller and allows for translational and rotational movements of the portable device while maintaining the proximate relationship between the planar charging surface and the planar receiving surface.

The portable device has a receiving coil 120 for receiving (that is, the receiving coil 120 is configured to receive) at least a portion of the magnetic charging field 106. The portable device also has a magnetometer 122 for generating a magnetic direction signal that is responsive to magnetic fields received by the portable device including the magnetic earthly field of the Earth and the magnetic charging field 106 of the inductive charging unit. The magnetic direction signal is indicative of a portion of a magnetic charging field received the portable device, by signifying (for example), the strength of the received field, the direction of the field, or the direction in which the field gets stronger or weaker. Magnetometer 122 includes scalar and vector magnetometers, including rotating coil, Hall Effect, magnetorestive, fluxgate, SDUID, and SERF magnetometers that are able to generate a magnetic direction signal. An exemplarily magnetometer produces a magnetic direction signal having three orthogonal components representing the conventional three dimensional X, Y and Z coordinates, each component having a signed magnitude representing the magnitude of the magnetic field received by the magnetometer in the direction of the component. The construction and operation of a magnetometer is known to those familiar with the art. When placed in a portable device, the X, Y and Z coordinates correspond to directional movement of the portable device. In one example, the X coordinate corresponds to a left-right direction of movement of the portable device relative to the planar charging surface; the Y coordinate corresponds to an up-down direction movement towards a top or bottom of the planar charging surface; and the Z coordinate corresponds to a towards-away direction of movement bringing the portable device closer or farther from the planar charging surface.

The receiving coil converts the received portion of the magnetic charging field 106 to electrical power which is conditioned by power manager 124 for either or both powering the portable device 110 and charging a power pack 126, which includes a rechargeable battery in this example. The better the alignment between the receiving coil and the charging coil, the greater the received portion of the magnetic charging field and the greater the amount of electrical power received. Power manager 124 may be configured to determine an amount or quantity of received power, and may further be configured to generate or supply an amount of received power signal to a controller 128 indicative of an amount of power received and converted from the magnetic charging field.

Electrical power is the product of voltage and current: an increase in the amount of received power includes either an increase in current at a constant voltage, an increase in the voltage at a constant current, or any other combination of voltage and current where the product of the voltage and current increases. Thus, in an example of a constant voltage application, an increase in the amount of received power corresponds to an increase in current received by the receiving coil because an increase in current at a constant voltage results in an increase of the product of the current and voltage, corresponding to an increase in power.

Controller 128 also receives the magnetic direction signal from the magnetometer 122. Controller 128 may include a microprocessor, microcontroller, DSP, custom circuitry, memory including non-transitory computer readable memory having stored instructions that when executed cause the portable device to implement various processes. Such process include a charging alignment process 130, in which controller 128 receives the magnetic direction signal from the magnetometer 122, and based upon that magnetic direction signal, generates a motion signal. The generated motion signal is indicative of an actual or potential movement of the portable device that does or would increase the portion of the magnetic charging field received by the portable device 110. In a typical scenario, the motion signal may indicate in which way the portable device 110 may be moved relative to inductive charging unit 100 or otherwise aligned so that the portable device 110 receives a stronger portion of the magnetic field. The motion signal may be determined and generated in any fashion, including by use of mathematical models. In many cases, the motion signal may be determined by utilizing a look-up table or calculation process 132. Processes that may be implemented by controller 128 may also include a magnetic earthly field processor 134 for implementing related processes which may include at least one of a compass process, a navigation process and an augmented reality process. A compass process may render a compass on a display with a vector pointing north as determined by the magnetic earthly field. A navigation process may render a map on a display with heading information indicating a direction of north, south, east or west movement of the portable device relative to the magnetic earthly field. An augmented reality process may render augmented camera images providing additional information based on the location and heading of the camera as determined at least in part relative to the magnetic earthly field. Compass, navigation and augmented reality processes are known to those familiar with the art.

Controller 128 also receives user input signals from user input 136. The user input 136 may include a touch screen, cameras, microphones, buttons, keyboard, track pad, touch pad and three dimensional gesture recognition means. The user input 136 allows for user control of various process of the portable device including the charging alignment process 130 and the magnetic earthly field processes 134. Controller 128 also interfaces with a display 138 which may include a color graphical display known to those familiar with the art.

Shown on the display 138 is a multiplicity of movement icons 140 for use by the charging alignment process. In a typical implementation, the motion signal generated by controller 128 may be made useful to a user by way of information presented or rendered on display 138. For example, display 138 may render one or more visual cues that inform the user how the portable device 110 may be moved or aligned so that the portable device 110 receives a stronger portion of the magnetic field. The visual cues may be rendered based upon the motion signal. FIG. 1 includes examples of such visual cues or movement icons, including arrows-for-movement icons indicative of translational motion and rotational motion of the portable device. Starting from the upper right, exemplarily movement icons include translational movement icons of right, up, left, down, up-right, up-left, down-left, and down-right, rotational movement icons include clockwise and counter clockwise, and an octagonal movement icon indicates a stopping of motion. Movement icons include still images, moving video images and other renderings. Numerous other movement icons may be used to indicate a movement of the portable device while remaining within the scope of the disclosure. Although visual cues may useful for many users, the visual cues may be supplanted or supplemented by audio cues, such as verbal instructions or a tone that changes in pitch or volume as the received magnetic field gets stronger or weaker.

In operation, a portable device 110 is placed on the planar charging surface 108 of an inductive charging unit 100 with the planar receiving surface 108 typically in contact with the planar charging surface. The transfer of power may be initiated automatically, semi-automatically or manually. To manually initiate, the user would enter a manual input at button 101 and at user input 136 causing the inductive charging unit to generate the magnetic charging field and the portable device to receive the magnetic charging field for provision of power to the portable device. The process could also begin automatically by the detection of the proximity of the portable device and the inductive charging unit in manner known to those familiar with the art. A semi-automatic process could include a state of operation enabling the automatic process.

In operation, if the transmitting coil and the receiving coil are not aligned then a smaller (or weaker) portion of magnetic charging field is received by the receiving coil. Thereafter, movement icons are rendered on the display of the portable device instruct the user how the move the portable device on the planar charging surface to increase the portion of the magnetic charging field received by the receiving coil. Processes for determining which movement icon(s) to render are described below. A stop motion icon is rendered based on a determination that the amount of magnetic charging field received by the receiving coil is adequate of if the transmitting coil is aligned with the receiving coil. By observing the movement icons, the user may, at a glance, position the portable device 110 on or near the inductive charging unit 100 so that the portable device 110 will receive a stronger portion of the charging field, and be charged more quickly or efficiently.

The charging alignment process has the advantage of facilitating manually locating a portable device on an inductive charging unit in a way that allows for a desired coupling of the magnetic charging field (or a good coupling under the circumstances). This is accomplished in an example without the use of alignment fiducial markings or surface coupling protrusions or indentations on either the portable device or the magnetic charging unit. The portable device can be aligned with any of a number of inductive charging units having transmitting coils of various sizes and shapes and the location of the receiving coil can be varied on the portable device. The charging alignment process utilizes a magnetometer in the determination of the movement icon. The magnetometer may already be incorporated on the portable device for the detection of the magnetic earthly field for applications such as a compass, navigation applications and virtual reality applications, thereby advantageously additional utility of the existing magnetometer.

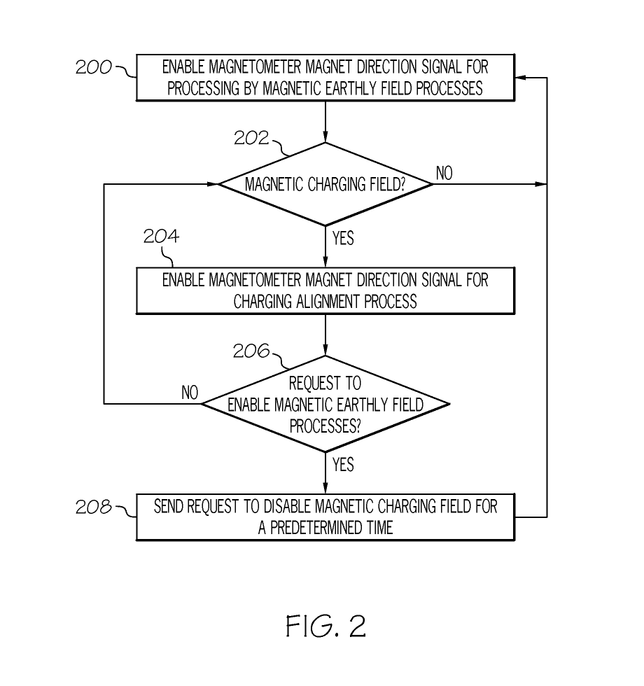

FIG. 2 illustrates a representative example of flow diagram for a portable device using a magnetometer for aligning the portable device on a planar charging surface of an inductive charging unit. Step 200 enables the magnetometer magnetic direction signal for processing by the magnetic earthly field processes. If a magnetic charging field is not determined in step 202, then the flow diagram returns to step 200. Detection of the magnetic charging field may be based on a manual input, a determination of an electrical signal generated at the receiving coil or the establishment of a communication link between the portable device and the inductive charging unit indicating a presence/absence state of the magnetic charging field. If the presence is determined, step 204 invokes a charging alignment process and enables the magnetometer magnetic direction signal for charging alignment purposes. Note that step 204 may optionally disable use of the magnetic direction signal for use by magnetic earthly field processes because the magnetic charging field may substantially interfere with the magnetic earthly field generated by the Earth. If a request to enable magnetic earthly field processes is determined at step 206, then step 208 sends a request to disable the magnetic charging field to the inductive charging unit. The magnetic field may be disabled until a subsequent request to enable the magnetic field is generated or after an elapsed time. The request can be generated by an application or process of the portable device or a manual input. For example, a navigation application operating while the portable device is placed upon the inductive charging unit may need to determine the magnetic heading of the device, or the charging alignment process may need to determine the magnetic earthly field to compensate for readings from the magnetic charging field. The request is sent to the inductive charging unit via an established communications interface. The request allows the magnet earthly field to be detected while the portable device is on the inductive charging unit. This may be done for compass or navigation purposes, or if the charging alignment process has an algorithm for compensating for the magnetic earthly field in the determination of alignment, by subtracting the magnetic earthly field from the magnetic direction signal generated by the magnetometer in the presence of the magnetic charging field.

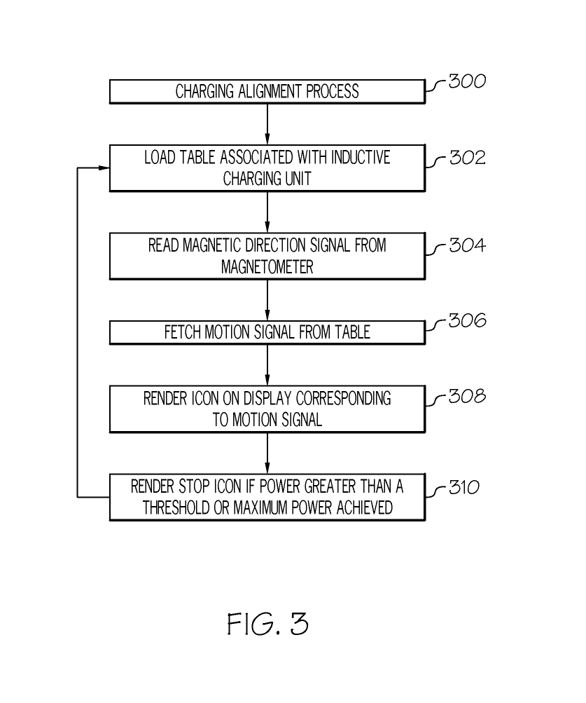

FIG. 3 illustrates a flow diagram of a first example of a charging alignment process using a magnetic direction signal from a magnetometer. The illustrated example of the charging alignment process is an example of the process invoked at step 204 as described above. The example of a charging alignment process is entered at step 300. Step 302 loads a look-up table associated with the inductive charging unit. In one example, only one look-up table may be used because the portable device only intends to interface with one inductive charging unit. In another example, the inductive charging unit may identify itself using the communication link with the portable device, or the portable device may optically recognize the inductive charging unit by an image of a bar code or QR code or other optical recognition approach. Alternately, a manual input on the user interface may be used to identify the inductive charging unit. Other approaches to identifying the inductive charging unit are within the scope of the description. Once identified, a look-up table associated with the inductive charging unit is loaded. The look-up table may be resident in memory of the portable device or may be loaded into the portable device from the Internet or other network through a wireless communication link such as WiFi, Bluetooth, LTE, GSM, CDMA or other links known to those familiar with the art. A look-up table includes a plurality of motion signals associated with magnetic direction signals. Based on a magnetic direction signal, generation of a corresponding motion signal results, motion signals include left, right, up, down, clockwise, counter clockwise and stop and are indicative of corresponding left, right, up, down, clockwise, counter clockwise and stop manual movements of the portable device. The look-up table may provide for X, Y, and Z components of the magnetic direction signal as well as corresponding magnitude and sign information of the components. In one example, the look-up table is generated by placing a reference device equivalent to the portable device 110 on a reference inductive charging unit equivalent to the inductive charging unit 100. For each of an array of locations across the planar charging surface, the magnetic direction signal from the magnetometer is read and the corresponding motion signal determined and entered into the look-up table. The motion signal for each location is intended to direct the manual movement of the device to align the receiving coil with the transmitting coil, thereby increasing the portion of the charging magnetic field received by the portable device. Step 304 reads the magnetic direction signal from the magnetometer and step 306 fetches the motion signal from the look-up table, thereby generating the motion signal. Step 308 renders a movement icon on the display corresponding to the motion signal. When a magnetic direction signal indicates that desired alignment is reached, a stop motion signal may be read from the look-up table and a stop movement icon rendered on the display. Optional step 310 determines if the amount of power received from the magnetic charging field is greater than a threshold and the stop icon may be rendered. The threshold may represent, for example, an amount of power that may be less than ideal or less than maximum, but that may satisfactory for practical purposes. This determination is made based on the received power signal generated by the power manager. This option allows for less than precise alignment of the transmitting and receiving coils if sufficient power is being received by the portable device, thereby simplifying and quickening the manual alignment process. For example, less operating power may be required by a device with a fully charged battery resulting in a less precise alignment needed to realize operating power without additional battery recharge power. Less precise coil alignment can simplify or quicken the user's manual alignment process.

In one example, the operation of the charging alignment process incorporates the physical locations of the magnetometer and the receiving coil of the portable device to adjust direction signals determined by the magnetometer to assist in the proper placement of the receiving coil relative to the transmitting coil. In some devices, the magnetometer and receiving coil may be arranged such that, when the magnetometer receives the strongest magnetic field, the receiving coil does as well. But in other devices, the magnetometer and receiving coil may be displaced relative to one another, such that each receives the magnetic field differently. Where there is such displacement, it may be possible that moving the portable device so that the magnetometer encounters a stronger magnetic field may cause the receiving coil to encounter a weaker field, or vice versa. Even if the magnetometer and receiving coil are displaced from one another, it still may be possible to use the magnetometer to position the receiving coil or to improve the alignment of the receiving coil with respect to the transmitting coil and the magnetic charging field. The below described processes allow magnetic field measurements determined by a magnetometer that is displaced from the receiving coil of the portable device to be used to properly place the receiving coil relative to the transmitting coil. Because the magnetometer measures components of a magnetic field generated by the transmitting coil and because the receiving coil is displayed from the magnetometer, direct measurement of magnetic fields by the magnetometer may not correspond to the desired alignment of the receiving coil with the transmitting coil. In an example, the physical design of the portable device (e.g., the position and distance of the magnetometer and receiving coil with respect to one another) is incorporated into processing of magnetic field measurements produced by the magnetometer to better assist in placement of the portable device based upon magnetometer measurements. In one example, a “direction of alignment” is determined based upon the physical design of the portable device, where the direction of alignment is a vector defining the direction between the magnetometer and the receiving coil of the portable device. Incorporating this “direction of alignment” into magnetometer measurements advantageously improves the utility of magnetic field measurements made by a magnetometer in aligning a receiving coil to a measured magnetic field, where the magnetometer is displayed from the receiving coil.

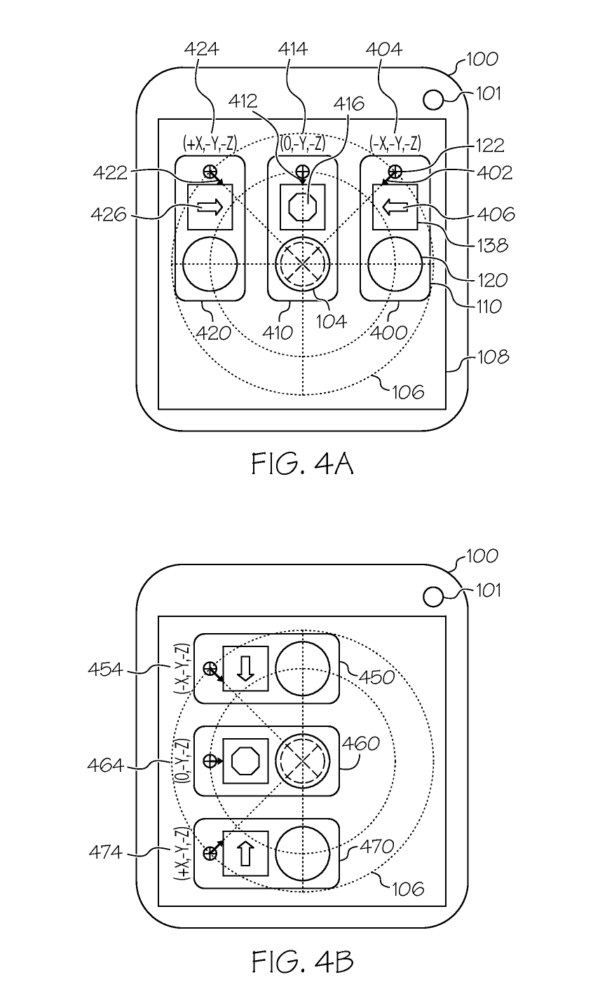

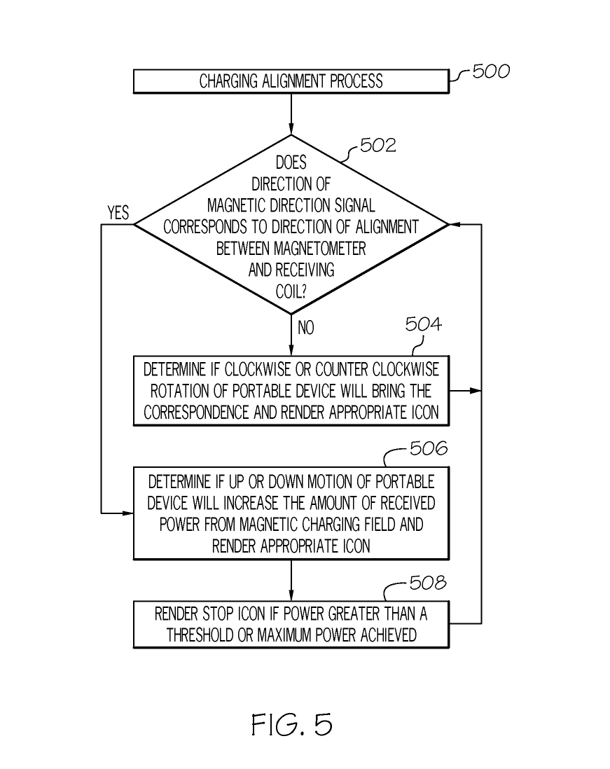

FIG. 4A illustrates a first example of aligning a portable device on a planar surface of an inductive charging unit with a magnetometer using the charging alignment process of FIG. 3. An inductive charging unit 100 has a button 101, a transmitting coil 104 shown as a dashed line circle with a centered diagonal cross, and a planar charging surface 108 transmitting a magnetic charging field 106 represented by fine dashed concentric circles with centered horizontal and vertical lines. A portable device 110 is shown in three different positions, right location 400, center location 410, and left location 420 on the planar charging surface 108. The portable device has a magnetometer 122 located at its top center, a display 138 and a receiving coil 120. Portable device location 410 shows the receiving coil aligned with the transmitting coil.

At location 400, the magnetometer produces a magnetic direction signal 402, indicated by an arrow pointing towards the transmitting coil, the arrow of the direction is in the lower left quadrant. The arrow corresponds to magnetic direction signal value 404 having a negative X component, a negative Y component and a negative Z component. The X and Y components are negative because arrow 402 is in the lower left magnetometer quadrant and the Z component is negative because the charging magnetic field is going into the magnetic charging surface. For the purposes of this example, the magnitude of X, Y and Z are not necessary to illustrate the operation of the charging alignment process. At location 400 with the magnetic direction signal of 404 and the knowledge of the transmitting coil and the receiving coil from the look-up table, the look-up table has a determined motion signal of “left” as shown by movement icon left arrow 406.

At location 410, the magnetometer produces a magnetic direction signal 412, indicated by an arrow pointing towards the transmitting coil; the arrow of the direction is in the magnetometer's lower quadrant centered between the left and right quadrants. The arrow corresponds to magnetic direction signal value 414 having a zero X component, a negative Y component and a negative Z component. The X is zero because arrow 412 is centered between the left and right quadrants, the Y component is negative because arrow 402 is in the lower half and the Z component is negative because the charging magnetic field is going into the magnetic charging surface. At location 410 with the magnetic direction signal of 414 and the knowledge of the transmitting coil and the receiving coil, the look-up table has a determined motion signal of “stop” as shown by movement icon octagon 416.

At location 420, the magnetometer produces a magnetic direction signal 422, indicated by an arrow pointing towards the transmitting coil; the arrow of the direction is in the magnetometer's lower right quadrant. The arrow corresponds to magnetic direction signal value 424 having a positive X component, a negative Y component and a negative Z component. The X is positive because arrow 422 is in the right half, the Y component is negative because arrow 402 is in the lower half and the Z component is negative because the charging magnetic field is going into the magnetic charging surface. At location 420 with the magnetic direction signal of 424 and the knowledge of the transmitting coil and the receiving coil, the look-up table has a determined motion signal of “right” as shown by movement icon 426 indicating a right arrow.

While only left and right movement arrows are shown, the look-up table corresponding to inductive charging unit can include any of the movement icons for moving the portable device upon the planar charging surface. In operation, a portable device at location 400 would be moved by the user to the left until the motion signal had a stop movement value at location 410. Note that if optional step 310 were applied the stop movement value of the motion signal could be generated between location 400 and location 410 based on the received power being greater than a threshold or reaching a maximum.

FIG. 4B illustrates a second example of aligning a portable device on a planar surface of an inductive charging unit with a magnetometer using the charging alignment process of FIG. 3. Note that three locations 400, 410, and 420 of FIG. 4A are rotated by ninety degrees as a group in FIG. 4B showing three corresponding locations 450, 460 and 470 to illustrate portable device rotational effects on the inductive charging surface having a circular magnetic charging field. Note further that directions signal values 454, 464 and 474 of FIG. 4B correspond to magnetic direction signal values 404, 414 and 424 of FIG. 4A respectively and based on the explanation of FIG. 4A produce the same respective movement icons. This is a result the symmetric magnetic charging field 186 with respect to the locations of FIG. 4A and FIG. 4B. Also note that the magnetometer of location 420 is in the same location on the magnetic charging surface as the magnetometer of location 450. However the portable device is rotated ninety degrees. This is evidenced by magnetic direction signal 424 having a positive X value and magnetic direction signal 454 having a negative X value. Nevertheless, the table based process aligns the receiving coil of the portable device with the transmitting coil of the inductive charging unit at locations 410 and 460.

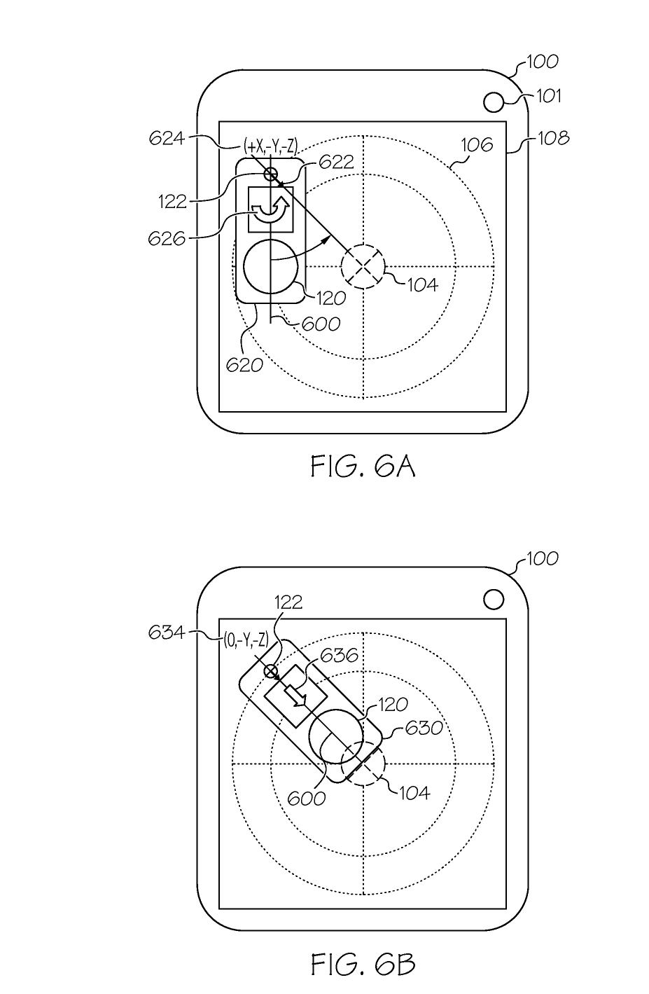

FIG. 5 illustrates a flow diagram of a second example of a charging alignment process using a magnetic direction signal from a magnetometer. In this example, the alignment generation of the motion signal results from calculation. A table look-up in not necessarily required. The charging alignment process invoked at step 204 is entered at step 500. Step 502 determines if the direction of the magnetic direction signal corresponds to the direction of alignment between the magnetometer and the receiving coil. In the portable device, the magnetometer has a first location and the receiving coil has a second location. The direction of alignment corresponds to a direction formed by the first and second locations, or a line passing between the magnetometer and the receiving coil. In the example of portable device 110, the direction corresponds a coordinate system centered at the magnetometer were where the coordinate X=0. If the magnetic direction signal has a corresponding value of X=0 then the direction of the magnetic direction signal corresponds to the direction of the alignment between the magnetometer and the receiving coil in the plane of the planar charging surface and corresponding plane of the planar receiving surface and the flow diagram proceeds to step 506. Otherwise, step 504 determines if a clockwise or a counter clockwise rotation of the portable device will bring a corresponding alignment. A corresponding motion signal is generated and a resulting motion icon is rendered on the display. In one example, a magnetic direction signal having positive value of X could result in a counter clockwise movement icon rendered on the display and a magnetic direction signal having a negative value of X could result in a clockwise movement icon rendered on the display. In another example, the either the clockwise or counter clockwise movement icon can be displayed until the X component of the magnetic direction signal were zero. The choice of clockwise or counter clockwise can be arbitrary, random, calculated or estimated on the basis of additional data not included in this example.

Based on a correspondence determined at step 502, then step 506 determines if an up or down motion will increase the amount of received power from the magnetic charging field and an appropriate movement icon is rendered on the display. The up or down movement corresponds to the movement of the receiving coil along a line forming a direction comprising the locations of the magnetometer and the receiving coil towards or away from the transmitting coil. As the receiving coil approaches the transmitting coil, the portion of the magnetic direction field received by the receiving coil increases which results in an increase in the amount of received power determined by the power manager. The movement icon continues to be rendered until at step 508 the amount of received power reaches a threshold indicative of the portable device receiving sufficient power for its needs, or the amount of received power reaches a maximum and begins to decrease, in which case a generated motion signal corresponds to a stop motion and the stop movement icon is rendered on the display. The up or down movement icon of step 506 may be generated randomly or arbitrarily and reversed if the initial motion icon is determined to be incorrect, such as by observing a decrease in received power. Alternately, the magnitude of the magnetic direction signal can be compared with the amount of received power to determine the initial up or down direction. If the magnetic direction signal magnitude indicates the distance form magnetometer to the transmitting coil is greater than the distance from the receiving coil to the transmitting coil, and then the down motion icon would be rendered, otherwise the up motion icon would be rendered.

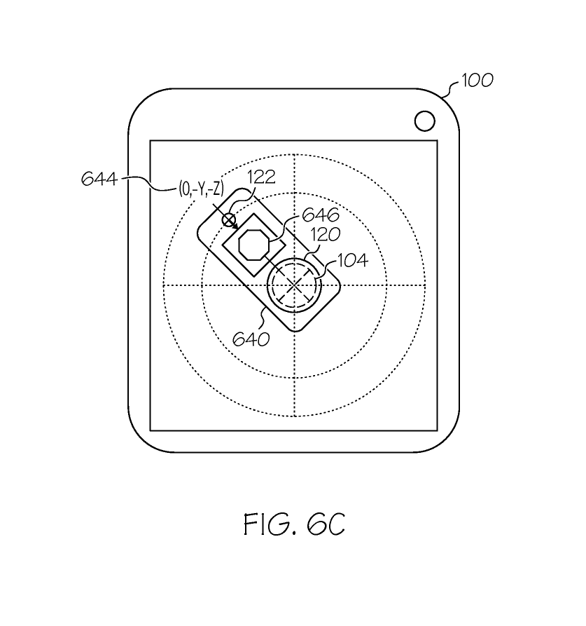

FIG. 6A, FIG. 6B and FIG. 6C illustrate an example of aligning a portable device on a planar surface of an inductive charging unit with a magnetometer using the charging alignment process of FIG. 5. An inductive charging unit 100 has a button 101, a transmitting coil 104 shown as a dashed line circle with a centered diagonal cross, and a planar charging surface 108 transmitting a magnetic charging field 106 represented by fine dashed concentric circles with centered horizontal and vertical lines. Portable device is shown in location 620. The portable device has a magnetometer 122 and a receiving coil 120. The magnetometer and the receiving coil have locations within the portable device that define a direction of alignment. The direction of alignment is shown by line 600 passing through the magnetometer and the receiving coil. The portable device in location 620 corresponds to the portable device in location 420 of FIG. 4. Magnetic direction signal 622 has a value 624 corresponding to value 424, which define a vector from the magnetometer to the transmitting coil. Since the X value of the magnetic direction signal in this example is positive, the charging alignment process of FIG. 5 generates a motion signal indicative of a counter clockwise movement of the portable device and a counter clockwise movement icon 626 is rendered on the display. In response, the portable device is manually rotated counter clockwise until the magnetometer 122, the receiving coil 120 and the transmitting coil 104 are aligned as shown in FIG. 6B. In other words, the portable device is manually rotated counter clockwise until the direction of the magnetic direction signal is aligned with the direction of alignment between the magnetometer and the receiving coil. FIG. 6B shows this alignment of the direction of the magnetic direction signal is aligned with the direction of the direction of alignment between the magnetometer and the receiving coil. This alignment is also indicated by the magnetic direction signal having a zero value for the X component corresponding to the alignment signal having a known value of zero for the X component as a result of its design and manufacture. A downward motion signal (relative to the case of the portable device) is generated and a downward movement icon 636 is displayed. The downward motion signal can be selected over the upward motion signal either arbitrarily, randomly or as a result of the relative readings of the magnetometer's magnetic direction signal magnitude and the amount of received power magnitude as determined by, for example, the power manager. If the relative magnetic strength readings, however, indicate that the magnetometer is closer to the transmitting coil than the receiving coil, then the upward motion signal is generated and the upward movement icon rendered. The portable device is manually moved in a downward motion relative to the portable device until the receiving coil is aligned with the transmitting coil as shown in FIG. 6C. The center of the transmitting coil 104 is shown to be aligned with the center of the receiving coil 120 which is also aligned with the magnetometer 122 as shown by a zero X value at the magnetic direction signal 644. The stop movement icon 646 can result either from the amount of received power exceeding a threshold or achieving a maximum.

In a different example, step 504 of FIG. 5 could determine a left or right movement instead of the above described rotational movement. Thus, the device in the location 620 has the X value of the magnetic direction signal that is positive, the charging alignment process in this example generates a motion signal indicative of a right movement of the portable device and a right movement icon is rendered on the display. Based on the icon, the portable device is manually moved right until the magnetometer 122, the receiving coil 120 and the transmitting coil 104 are aligned. This alignment is determined by the magnetic direction signal having a zero value for the X component corresponding to the alignment signal having a value of zero for the X component. In one example, it is the design an manufacture of the portable device that determines an X component of zero when the received magnetic field is aligned with a vector from the magnetometer to the receiving coil. Thereafter, a downward motion, upward motion or stop motion signal is generated as previously described. In this example, the stop motion signal would be generated because a right movement of the portable device in position 620 results in the receiving coil being aligned with the charging coil, similar to the showing of the portable device at location 410 of FIG. 4A.

Note that in referring to FIG. 4 and FIG. 6, the description shows a portable device in locations 420, 450 and 620 having a magnetometer in a common initial position on a planar charging surface. However, because of differing orientations and charging alignment processes, the portable may have a receiving coil that is aligned over the transmitting coil, but with different orientations. Illustrated are three different orientations: one vertical orientation 410, one horizontal orientation 460, and one orientation between horizontal and vertical 640. While FIG. 5 shows process for rotating the portable device and then moving the device with a translational motion, other processes can combine the rotation and translational motions into a common direction motion. In another example, those familiar with the art will appreciate that the processes of FIG. 5 can be accomplished entirely with translational motions and no rotational motions. Also, other examples may combine both the table based process of FIG. 3 with the calculation based process of FIG. 5 to provide for another example of a charging alignment process while remaining within the scope of the disclosure. For example, a first motion signal can be generated by the table based process of FIG. 3 and a second motion signal can be generated by the calculation based process of FIG. 5 and the movement icon rendered based on an average or quality determination of both the first and second motion signals. Furthermore, in another example, the portable device can be designed to locate the magnetometer in the other locations within the portable device, including the center of the receiving coil, and the described charging alignment processes would function to increase the portion of the magnetic charging field received by the receiving coil of the portable device.

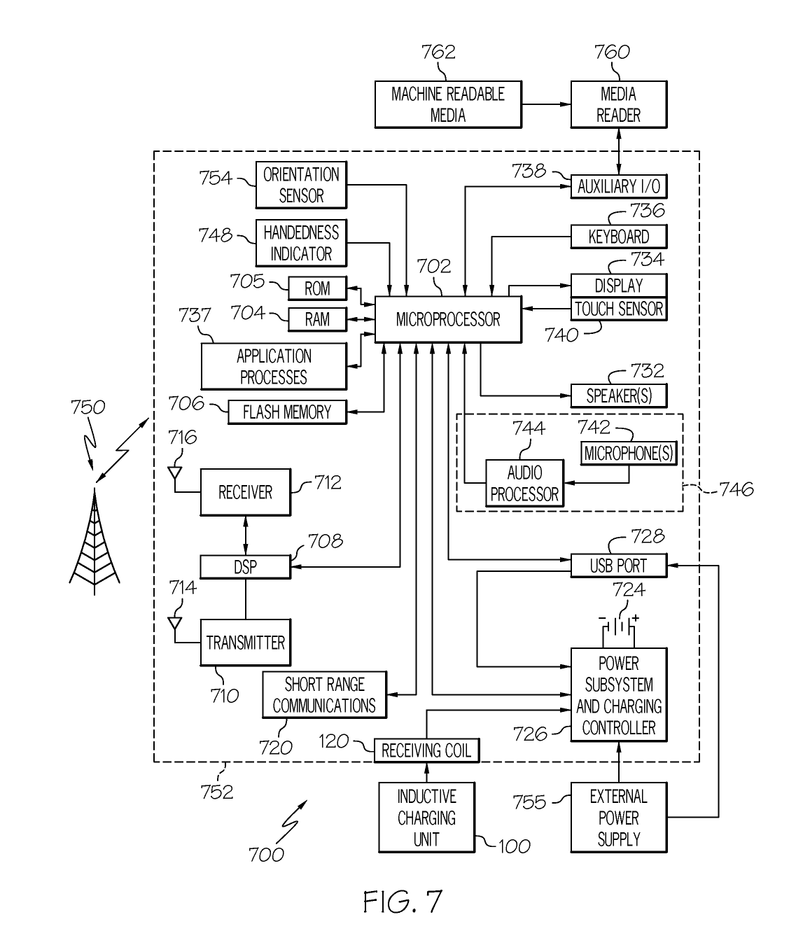

FIG. 7 illustrates a representative block diagram of an electronic device and associated components 700 that are able to include the above described systems and perform the above described methods. Electronic device 752 correspond to portable device 110 and in this example, electronic device 752 is a wireless two-way communication device, such as a smartphone, with voice and data communication capabilities. Such electronic devices communicate with a wireless network 750, which is able to include a wireless voice network, a wireless data network, or both, that use one or more wireless communications protocols. Wireless voice communications are performed using either an analog or digital wireless communication channel. Data communications allow the electronic device 752 to communicate with other computer systems via the Internet. Examples of electronic devices that are able to incorporate the above described systems and methods include, for example, a data messaging device, a two-way pager, a cellular telephone with data messaging capabilities, a wireless Internet appliance or a data communication device that may or may not include telephony capabilities.

The illustrated electronic device 752 is an example electronic device that includes two-way wireless communications functions. Such electronic devices incorporate a wireless communication component that includes a wireless communications subsystem including elements such as a wireless transmitter 710, a wireless receiver 712, and associated components such as one or more antenna elements 714 and 716. A digital signal processor (DSP) 708 performs processing to extract data from received wireless signals and to generate signals to be transmitted. The particular design of the communication subsystem is dependent upon the wireless communications network and associated wireless communications protocols with which the device is intended to operate.

The electronic device 752 includes a microprocessor 702 that controls the overall operation of the electronic device 752. The microprocessor 702 interacts with the above described communications subsystem elements and also interacts with other device subsystems such as flash memory 706, random access memory (RAM) 704, read only memory (ROM) 705 which is a non-transitory computer readable media device including computer instructions, stored instructions and/or a stored set of instruction, auxiliary input/output (I/O) device 738, USB Port 728, display 734, touch sensor 740, keyboard 736, pressures sensing transducers(s) 731 and speaker(s) 732 coupled to acoustic port(s) 733, audio processor 744, a short-range communications subsystem 720, an orientation sensor 754, a handedness indicator 748, a power subsystem and charging controller 726, and any other device subsystems.

The electronic device 752 in one example further includes an orientation sensor 754. Various electronic devices are able to incorporate one or more orientation sensors that include, for example, accelerometer or gyroscope based orientation sensors, light sensors that are located at locations on a case of the electronic device. In some examples, the orientation sensor produces an indication of the current orientation of the electronic device relative to the ground.

The electronic device 752 in one example includes an audio subsystem 746 that includes an audio processor 744, and a plurality of microphones 742. The audio processor 744 may be an ASIC, FPGA or DSP or other type integrated circuit.

A power pack 724 is connected to a power subsystem and charging controller 726. The power pack 724 provides or supplies power to the circuits of the electronic device 752. The power subsystem and charging controller 726 includes power distribution circuitry for providing power to the electronic device 752 and also contains power pack charging controller circuitry to manage recharging the power pack 724. By way of example, the power pack includes a rechargeable battery for making device 752 a battery operated device. Also included is receiving coil 120 shown coupled to inductive charging unit 100 and power subsystem and charging controller 726 which includes functions of power manager 124.

The USB port 728 provides data communication between the electronic device 752 and one or more external devices. Data communication through USB port 728 enables a user to set preferences through the external device or through a software application and extends the capabilities of the device by enabling information or software exchange through direct connections between the electronic device 752 and external data sources rather than through a wireless data communication network. The software exchange can be with microprocessor 702 or audio processor 744 or both as circumstances require.

Operating system software used by the microprocessor 702 is stored in flash memory 706 and/or ROM 705. Further examples are able to use a power pack backed-up RAM or other non-volatile storage data elements to store operating systems, other executable programs, or both. The operating system software, device application software, or parts thereof, are able to be temporarily loaded into volatile data storage such as RAM 704. Data received via wireless communication signals or through wired communications are also able to be stored to RAM 704.

The microprocessor 702, in addition to its operating system functions, is able to execute software applications on the electronic device 752. A set of applications that control basic device operations, including at least data and voice communication applications, is able to be installed on the electronic device 752 during manufacture. Examples of applications that are able to be loaded onto the device may be included in application processes 737 and may include magnetic earthly field processes 134, charging alignment process 130 and a personal information manager (PIM) application having the ability to organize and manage data items relating to the device user, such as, but not limited to, e-mail, calendar events, voice mails, appointments, and task items.

Further applications may also be loaded onto the electronic device 752 through, for example, the wireless network 750, an auxiliary I/O device 738, USB port 728, short-range communications subsystem 720, or any combination of these interfaces. Such applications are then able to be installed by a user in the RAM 704 or a non-volatile store for execution by the microprocessor 702.

In a data communication mode, a received signal such as a text message or web page download is processed by the communication subsystem, including wireless receiver 712 and wireless transmitter 710, and communicated data is provided the microprocessor 702, which is able to further process the received data for output to the display 734, or alternatively, to an auxiliary I/O device 738 or the USB port 728. A user of the electronic device 752 may also compose data items, such as e-mail messages, using the keyboard 736, which is able to include a complete alphanumeric keyboard or a telephone-type keypad, in conjunction with the display 734 and possibly an auxiliary I/O device 738. Such composed items are then able to be transmitted over a communication network through the communication subsystem.

For voice communications, overall operation of the electronic device 752 is substantially similar, except that received signals are generally provided to a speaker 732 and signals for transmission are generally produced by at least one of the plurality of microphones 742. Alternative voice or audio I/O subsystems, such as a voice message recording subsystem, may also be implemented on the electronic device 752. Although voice or audio signal output is generally accomplished primarily through the speaker(s) 732, the display 734 may also be used to provide an indication of the identity of a calling party, the duration of a voice call, or other voice call related information, for example.

Depending on conditions or statuses of the electronic device 752, one or more particular functions associated with a subsystem circuit may be disabled, or an entire subsystem circuit may be disabled. For example, if the power pack temperature is high, then voice functions may be disabled, but data communications, such as e-mail, may still be enabled over the communication subsystem.

A short-range communications subsystem 720 is a further optional component which may provide for communication between the electronic device 752 and different systems or devices, which need not necessarily be similar devices. For example, the short-range communications subsystem 720 may include an infrared device and associated circuits and components or a Radio Frequency based communication module such as one supporting Bluetooth® communications, to provide for communication with similarly-enabled systems and devices.

A media reader 760 is able to be connected to an auxiliary I/O device 738 to allow, for example, loading computer readable program code of a computer program product into the electronic device 752 for storage into flash memory 706 or in memory of audio processor 744. One example of a media reader 760 is an optical drive such as a CD/DVD drive, which may be used to store data to and read data from a computer readable medium or storage product such as computer readable storage media 762. Examples of suitable computer readable storage media include optical storage media such as a CD or DVD, magnetic media, or any other suitable data storage device. Media reader 760 is alternatively able to be connected to the electronic device through the USB port 728 or computer readable program code is alternatively able to be provided to the electronic device 752 through the wireless network 750.

### Information Processing System

The present subject matter can be realized in hardware, software, or a combination of hardware and software. A system can be realized in a centralized fashion in one computer system, or in a distributed fashion where different elements are spread across several interconnected computer systems. Any kind of computer system, or other apparatus adapted for carrying out the methods described herein, is suitable. A typical combination of hardware and software could be a general purpose computer system with a computer program that, when being loaded and executed, controls the computer system such that it carries out the methods described herein.

The present subject matter can also be embedded in a computer program product, which comprises all the features enabling the implementation of the methods described herein, and which, when loaded in a computer system, is able to carry out these methods. Computer program in the present context means any expression, in any language, code or notation, of a set of instructions intended to cause a system having an information processing capability to perform a particular function either directly or after either or both of the following a) conversion to another language, code or, notation; and b) reproduction in a different material form.

Each computer system may include, inter alia, one or more computers and at least a computer readable medium allowing a computer to read data, instructions, messages or message packets, and other computer readable information from the computer readable medium. The computer readable medium may include computer readable storage medium embodying non-volatile memory, such as read-only memory (ROM), flash memory, disk drive memory, CD-ROM, and other permanent storage and may be considered as non-transitory computer readable medium having a stored set of instructions that when executed implement processes described herein. Additionally, a computer medium may include volatile storage such as RAM, buffers, cache memory, and network circuits. Furthermore, the computer readable medium may comprise computer readable information in a transitory state medium such as a network link and/or a network interface, including a wired network or a wireless network, which allow a computer to read such computer readable information.

Non-Limiting Examples

Although specific embodiments of the subject matter have been disclosed, those having ordinary skill in the art will understand that changes can be made to the specific embodiments without departing from the scope of the disclosure. The scope of the disclosure is not to be restricted, therefore, to specific embodiments or examples, and it is intended that the appended claims define the scope of the present disclosure.

What is claimed is:

1. A method in a portable device comprising:
receiving a magnetic direction signal from a magnetometer, the magnetic direction signal indicative of a portion of a magnetic charging field received the portable device; and
generating, based on the magnetic direction signal, a motion signal indicative of a movement of the portable device, the movement determined to increase the portion of the magnetic charging field received by the portable device.

2. The method according to claim 1 wherein the magnetometer also receives a magnetic earthly field and the method further comprises processing the magnetic direction signal to determine a direction of the magnetic earthly field based on a determined absence of the magnetic charging field.

3. The method according to claim 2 wherein the processing includes processing the magnetic direction signal by at least one of a compass process, a navigation process and an augmented reality process.

4. The method according to claim 1 further comprising rendering a movement icon on a display of the portable device, the movement icon based upon the motion signal.

5. The method according to claim 4 wherein the movement icon is indicative of at least one of a translational motion of the portable device and a rotational motion of the portable device.

6. The method according to claim 1 wherein the motion signal is generated based on the magnetic direction signal and a look-up table.

7. The method according to claim 1 wherein the portable device includes a receiving coil for receiving the portion of the magnetic charging field and producing an amount of received power, and the motion signal is indicative of a direction of movement that increases the portion of the magnetic charging field received by the receiving coil.

8. The method according to claim 7 wherein the portable device includes a power manager coupled to the receiving coil, the power manager determining the amount of received power and the generating generates the motion signal further based on the amount of received power.

9. The method according to claim 8 wherein the motion signal is indicative of a stopping of the movement based on the amount of received power being greater than a threshold.

10. The method according to claim 7 wherein the magnetometer and the receiving coil have locations within the portable device that define a direction of alignment, and further wherein the motion signal is generated based on the magnetic direction signal and the direction of alignment.

11. A portable device comprising:
a receiving coil for receiving a portion of a magnetic charging field;
a magnetometer for generating a magnetic direction signal indicative of the magnetic charging field; and
a controller for generating a motion signal based on the magnetic direction signal, the motion signal indicative of a movement of the portable device determined to increase the portion of the magnetic charging field received by the receiving coil.

12. The portable device according to claim 11 wherein the magnetometer also receives a magnetic earthly field and the controller processes the magnetic direction signal to determine a direction of the magnetic earthly field based on a determined absence of the magnetic charging field, and the portable device further comprises a magnetic earthly field processor for implementing at least one of a compass process, a navigation process and an augmented reality process based on the direction of the magnetic earthly field.

13. The portable device according to claim 11 further comprising a display for rendering a movement icon indicative of the motion signal, the movement icon being indicative of at least one of a translational motion of the portable device and a rotational motion of the portable device.

14. The portable device according to claim 11 wherein the receiving coil receives the portion of the magnetic charging field and produces an amount of received power and the motion signal is determined to increase the portion of the magnetic charging field received by the receiving coil, and the portable device further comprises
a power manager coupled to the receiving coil for determining the amount of received power and the motion signal is further generated based on the amount of received power,
wherein the magnetometer and the receiving coil have locations within the portable device that define a direction of alignment, and further wherein the motion signal is generated based on the direction of alignment.

15. A non-transitory computer readable medium having a stored set of instructions that when executed cause an apparatus to:
process a magnetic direction signal indicative of a portion of a magnetic charging field transmitted at a planar charging surface of an inductive charging unit and received at a planar receiving surface of a portable device, the planar receiving surface being proximate to the planar charging surface;
generate a motion signal indicative of a manual movement of the portable device determined to increase the portion of the magnetic charging field received by the portable device based on the magnetic direction signal; and
process the magnetic direction signal to determine a direction of a magnetic earthly field based on a determined absence of the magnetic charging field.
